(19) United States
(12) Patent Application Publication
(10) Pub. No.: US 2009/0075436 A1
(43) Pub. Date: Mar. 19, 2009

(54) METHOD OF MANUFACTURING A THIN-FILM TRANSISTOR

(76) Inventors: Seong-kweon Heo, Suwon-si (KR); Chun-gi You, Hwaseong-si (KR)

Correspondence Address: F. CHAU & ASSOCIATES, LLC, 130 WOODBURY ROAD, WOODBURY, NY, 11797, US

(21) Appl. No.: 12/194,660

(22) Filed: Aug. 20, 2008

(30) Foreign Application Priority Data
Sep. 18, 2007 (KR) 10-2007-0094915

(51) Int. Cl. H01L 29/04; H01L 29/786

(52) U.S. Cl. 438/150; 438/487; 257/E29.273; 257/E29.004

(57) ABSTRACT

A method of manufacturing a thin-film transistor (TFT) includes forming an amorphous silicon layer on a substrate, crystallizing the amorphous silicon layer into a polycrystalline silicon layer using a laser beam, and selectively etching a protrusion formed at a grain boundary in the polycrystalline silicon layer using a hydroxide etchant.

This application claims priority from Korean Patent Application No. 10-2007-0094915 filed on Sep. 18, 2007, the disclosure of which is incorporated herein by reference in its entirety.

### BACKGROUND OF THE INVENTION

1. Technical Field

The present disclosure relates to a thin-film transistor (TFT), and more particularly, to a method of manufacturing a polycrystalline TFT using a laser beam.

2. Discussion of the Related Art

Polycrystalline silicon TFTs (poly-Si TFTs) are used in liquid crystal displays (LCDs) as switching devices. The poly-Si TFTs can be operated at high speed. Thus, an enhanced image quality can be achieved in an LCD device using the poly-Si TFTs.

When forming a polycrystalline silicon layer through laser crystallization, grains are formed and grown through laser melting and solidification. However, as each grain grows, protrusions are formed at grain boundaries at which neighboring grains meet with each other. The protrusions cause a non-uniform surface morphology, increase leakage current or reduce the breakdown voltage of a gate insulating film. That is, the protrusions deteriorate electrical characteristic of a polycrystalline TFT.

### SUMMARY OF THE INVENTION

Exemplary embodiments of the present invention provide a method of manufacturing a thin-film transistor (TFT), in which polycrystalline silicon having superior electrical characteristics can be obtained.

According to an exemplary embodiment of the present invention, a method of manufacturing a thin-film transistor (TFT) comprises forming an amorphous silicon layer on a substrate, crystallizing the amorphous silicon layer into a polycrystalline silicon layer using a laser beam, and selectively etching a protrusion formed at a grain boundary in the polycrystalline silicon layer using a hydroxide etchant.

The hydroxide etchant may have a higher etch rate for silicon than for silicon oxide.

A silicon oxide film can be formed on the polycrystalline silicon layer while the amorphous silicon layer is crystallized, and the silicon oxide film formed on the protrusion of the polycrystalline silicon layer can be thinner than the silicon oxide film formed on portions of the polycrystalline silicon layer other than the protrusion.

The hydroxide etchant may comprise tetramethyl ammonium hydroxide (TMAH).

The hydroxide etchant may comprise about 1 wt % to about 5 wt % of TMAH, about 0.1 wt % to about 3 wt % of additives, and de-ionized water.

The selective etching of the protrusion can be performed at a temperature of about 60° C. to 90° C.

The hydroxide etchant may comprise potassium hydroxide (KOH).

The hydroxide etchant may comprise about 5 w % to about 15 wt % of KOH, about 0.1 wt % to about 3 wt % of additives, and de-ionized water.

The selective etching of the protrusion can be performed at a temperature of about 30° C. to 70° C.

The selective etching of the protrusion can be performed at an etch rate of about 5 nm/min to about 15 nm/min.

Polycrystalline silicon, forming the protrusion, may have a (111) crystallographic orientation.

The protrusion may comprise an upper portion and a lower portion, wherein the upper portion can have a narrower width and a steeper inclination than the lower portion, and the selective etching of the protrusion may comprise removing the upper portion of the protrusion.

A sequential lateral solidification (SLS) method can be used in the crystallizing of the amorphous silicon layer.

The method may further comprise forming a gate insulating film on the polycrystalline silicon layer, forming a gate electrode on the gate insulating film, and forming a source electrode and a drain electrode which are electrically connected to the polycrystalline silicon layer adjacent both sides of the gate electrode.

### BRIEF DESCRIPTION OF THE DRAWINGS

Exemplary embodiments of the present invention can be understood in more detail from the following descriptions taken in conjunction with the accompanying drawings, in which:

FIG. 1 is a cross-sectional view of a substrate having a crystallized silicon layer formed using a method of manufacturing a thin-film transistor (TFT) according to an exemplary embodiment of the present invention;

FIG. 2A is an enlarged view of a protrusion shown in FIG. 1 according to an exemplary embodiment of the present invention;

FIG. 2B is a cross-sectional view of the protrusion of FIG. 2A after being selectively etched according to an exemplary embodiment of the present invention;

FIG. 3A is a scanning electron microscope (SEM) image of the protrusion of FIG. 2A before be selectively etched;

FIG. 3B is an SEM image of the protrusion of FIG. 2B after being selectively etched according to an exemplary embodiment of the present invention; and

FIGS. 4 through 11 are cross-sectional views sequentially showing a method of manufacturing a TFT according to an exemplary embodiment of the present invention.

### DETAILED DESCRIPTION OF EXEMPLARY EMBODIMENTS

The present invention will now be described more fully with reference to the accompanying drawings, in which exemplary embodiments of the invention are shown. The invention may, however, be embodied in many different forms and should not be construed as being limited to the embodiments set forth herein.

It will be understood that, when an element or layer is referred to as being “on” another element or layer, the element or layer can be directly on another element or layer or intervening elements or layers may be present.

Examples of liquid crystal displays (LCDs) used in the present disclosure include small and mid-sized displays, such as portable multimedia players (PMPs), personal digital assistants (PDAs), portable digital versatile disk (DVD) players, cellular phones, notebooks, digital still cameras (DSCs) and digital still videos (DSVs), and mid and large-sized displays such as digital televisions.

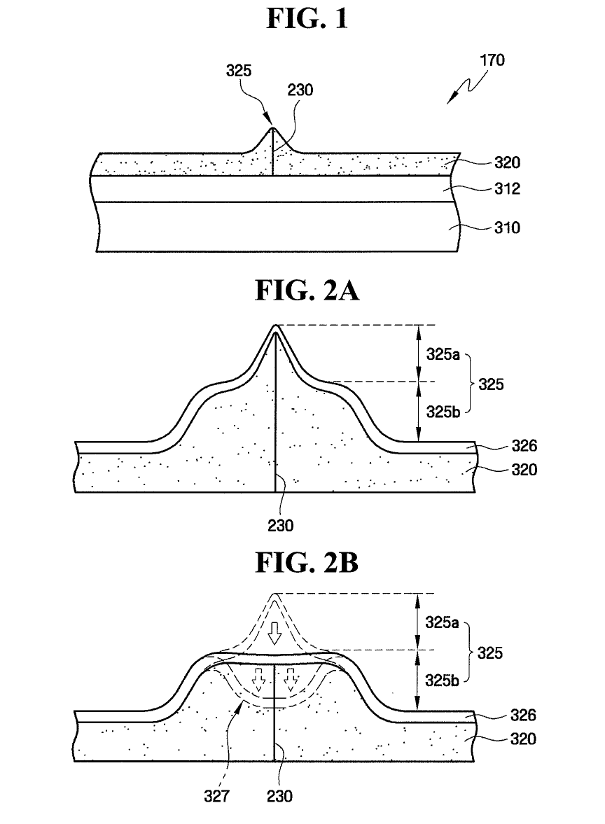

Referring to FIGS. 1 through 2B, a method of manufacturing a thin-film transistor (TFT) according to an exemplary embodiment of the present invention is described. FIG. 1 is a cross-sectional view of a substrate 170 having a crystallized silicon layer formed using a method of manufacturing a TFT according to an exemplary embodiment of the present invention. FIG. 2A is an enlarged view of a protrusion 325 shown in FIG. 1. FIG. 2B is a cross-sectional view of the protrusion 325 of FIG. 2A after being selectively etched according to an exemplary embodiment of the present invention.

In an exemplary embodiment of the present invention, an excimer laser annealing (ELA) method or a sequential lateral solidification (SLS) method may be used to crystallize amorphous silicon into polycrystalline silicon.

The ELA method partially melts amorphous silicon by irradiating a pulsed laser beam onto the amorphous silicon for a short period of time, for example, approximately 30 nanoseconds to approximately 200 nanoseconds, and then solidifies the melted amorphous silicon into polycrystalline silicon.

The SLS method completely melts amorphous silicon by irradiating a laser beam passed through a patterned mask to a predetermined region of the amorphous silicon and then solidifies the melted amorphous silicon into polycrystalline silicon. In an exemplary embodiment of the present invention, the laser beam or a stage on which the amorphous silicon is placed is moved. Then, the laser beam is irradiated again to previously formed grains to continuously grow the size of the grains. The previously formed grains function as seeds in the process.

Referring to FIG. 1, the silicon layer is melted with a high-temperature laser beam and then solidified to crystallize amorphous silicon. Accordingly, the silicon layer undergoes phase transformation from a relatively high-density liquid phase to a low-density solid phase. As a result, the protrusion 325, which deteriorates electrical characteristics of a TFT, is formed at a grain boundary 230. At the grain boundary 230, neighboring grains meet each other. In the SLS method, since amorphous silicon is crystallized after being completely melted, a larger protrusion may be formed at the grain boundary 230. The substrate 170 includes a transparent substrate 310, a buffer layer 312, and a polycrystalline silicon layer 320.

Referring to FIGS. 2A and 2B, a method of selectively etching and removing the protrusion 325, or reducing the height of the protrusion 325 is described according to an exemplary embodiment of the present invention.

Referring to FIG. 2A, when amorphous silicon is melted and then crystallized, a silicon oxide film 326 is formed on a surface of the polycrystalline silicon layer 320 through reaction between silicon atoms on the surface of the polycrystalline silicon layer 320 and oxygen atoms in a surrounding ambient during crystallization process. In an exemplary embodiment, the silicon oxide film 326 formed on the protrusion 325 of the polycrystalline silicon layer 320 is thinner than the silicon oxide film 326 formed on portions of the polycrystalline silicon layer 320.

The protrusion 325 formed at the boundary 230 includes an upper portion 325a and a lower portion 325b. The upper portion 325a has a narrow width and a steep slope, and the lower portion 325b has a wide width and a gentle slope. For example, if each height of the upper portion 325a and the lower portion 325b is approximately 30 nm to approximately 60 nm, the total height of the protrusion 325 is approximately 60 nm to approximately 120 nm. Since the protrusion 325 is higher than the other portions of the polycrystalline silicon layer 320, it may cause a non-uniform surface morphology, increase leakage current, or reduce the breakdown voltage of a gate insulating film. That is, the protrusion 325 may deteriorate electrical characteristics of the TFT. The silicon oxide film 326 covering the upper portion 325a is thinner than the silicon oxide film 326 covering the lower portion 325b.

In an exemplary embodiment of the present invention, the protrusion 325 may be removed or the height of the protrusion 325 may be reduced using a hydroxide etchant. The hydroxide etchant is a compound etchant containing a hydroxyl (OH) radical as an atomic group or radical. Hydroxide ions (OH⁻) generated from the hydroxide etchant have a higher etch rate for silicon than for silicon oxide. The etch rate of the hydroxide etchant for silicon may be several tens of times higher than the etch rate of the hydroxide etchant for silicon oxide.

Referring to FIG. 2B, when the hydroxide etchant is applied to the protrusion 325, the upper portion 325a of the protrusion 325 is etched before the lower portion 325b since the silicon oxide film 326 formed on the upper portion 325a of the protrusion 325 is thinner than the silicon oxide film 326 formed on the lower portion 325b. That is, the entire silicon oxide film 326 is etched by the hydroxide etchant at a low speed. Since the silicon oxide film 326 formed on the upper portion 325a of the protrusion 325 is thinner than the silicon oxide film 326 formed on the lower portion 325b, a portion of the polycrystalline silicon layer 320 corresponding to the upper portion 325a of the protrusion 325 is exposed to the hydroxide etchant prior to a portion of the polycrystalline silicon layer 320 corresponding to the lower portion 325b. Thus, the portion of the polycrystalline silicon layer 320 corresponding to the upper portion 325a of the protrusion 325 is etched prior to the portion of the polycrystalline silicon layer 320 corresponding to the lower portion 325b of the protrusion 325.

After a predetermined period of time, the upper portion 325a of the protrusion 325 is removed, and the lower portion 325b of the protrusion 325 remains. In this state, a top surface of the protrusion 325 is substantially flat. If the upper portion 325a of the protrusion 325 is over-etched, a groove 327 may be formed in the lower portion of the protrusion 325. Since the silicon oxide film 326 covering the portions of the polycrystalline silicon layer 320 other than the protrusion 325 is thick, the polycrystalline silicon layer 320 beneath the thick silicon oxide film 326 is not etched while the protrusion 325 is etched. Thus, the substrate 170 can have a uniform surface morphology.

The hydroxide etchant may contain tetramethyl ammonium hydroxide (TMAH). For example, the hydroxide etchant may contain about 1 wt % to about 5 wt % of TMAH, about 0.1 wt % to about 3 wt % of additives, and de-ionized water to obtain a higher etch rate for silicon than for silicon oxide. A reaction temperature for obtaining an appropriate etch rate for silicon, for example, about 5 nm/min to about 15 nm/min, may be approximately 60° C. to approximately 90° C. If the manufacturing conditions are out of the above ranges, the whole surface of the substrate 170 may be etched to cause the surface morphology non-uniform. Alternatively, the etching rate of the hydroxide etchant may be decreased, so that the protrusion 325 may not be sufficiently etched.

The hydroxide etchant may contain potassium hydroxide (KOH). For example, the hydroxide etchant may contain about 5 wt % to about 15 wt % of KOH, about 0.1 wt % to about 3 wt % of additives, and de-ionized water to obtain a higher etch rate for silicon than for silicon oxide. The reaction temperature for obtaining an appropriate etch rate for silicon, for example, about 5 nm/min to about 15 nm/min, may be approximately about 30° C. to about 70° C. In an exemplary embodiment, the reaction temperature is about 40° C. to about 45° C. If the manufacturing conditions are out of the above ranges, the whole surface of the substrate 170 may be etched to cause the surface morphology non-uniform. Alternatively, the etching rate of the hydroxide etchant may be decreased, so that the protrusion 325 may not be sufficiently etched.

To obtain a low etch rate for silicon, for example, about 5 nm/min to about 15 nm/min, using the hydroxide etchant, a portion of the polycrystalline silicon layer 320 corresponding to the protrusion 325 may have a (111) crystallographic orientation. If the portion of the polycrystalline silicon layer 320 has a crystallographic orientation other than the (111) orientation, the etch rate of the hydroxide etchant for silicon may increase, which, in turn, makes it difficult to obtain a high etch selectivity.

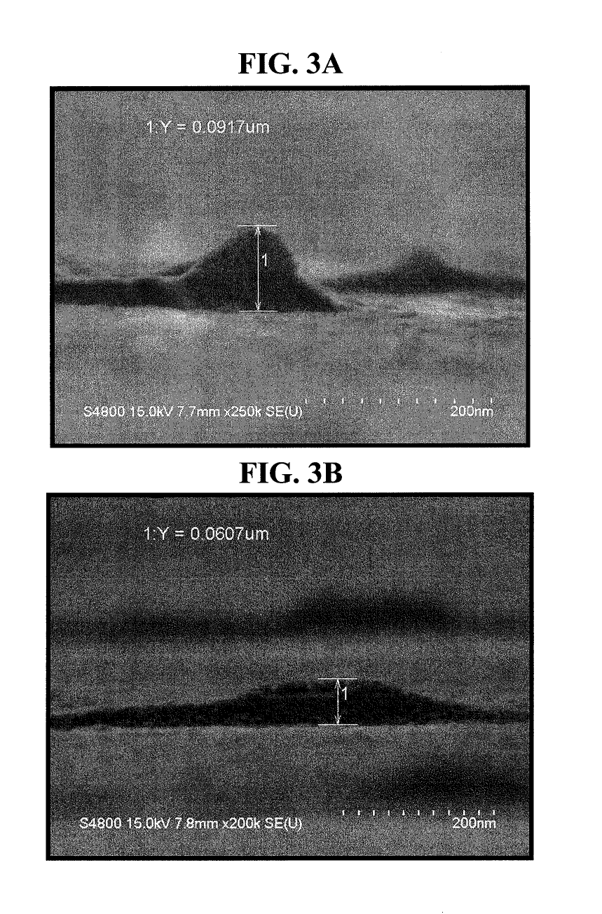

FIG. 3A is a scanning electron microscope (SEM) image of the protrusion of FIG. 2A before be selectively etched, and FIG. 3B is an SEM image of the protrusion of FIG. 2B after being selectively etched according to an exemplary embodiment of the present invention.

That is, the protrusion of FIG. 3A is selectively etched using the hydroxide etchant to be the protrusion of FIG. 3B. The height of protrusion of FIG. 3A was 91.7 nm. After selectively etching process, the height of the protrusion of FIG. 3B was 60.7 nm. The upper portion of the protrusion was selectively etched.

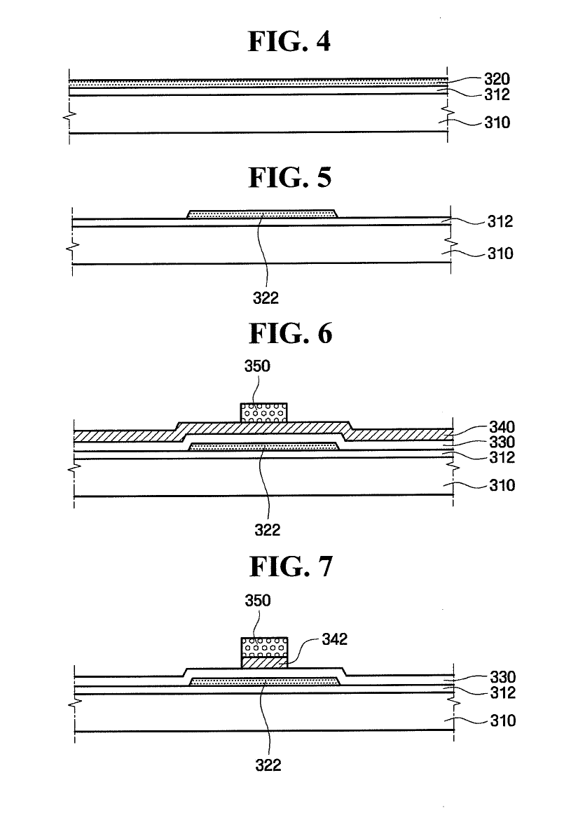

Referring to FIGS. 4 through 11, a method of manufacturing a TFT, in which polycrystalline silicon is used as a channel region, is described. FIGS. 4 through 11 are cross-sectional views showing a method of manufacturing a TFT according to an exemplary embodiment of the present invention.

Referring to FIG. 4, a buffer layer 312, which is a silicon oxide film or a stacked layer with a silicon nitride film, is formed on a transparent substrate 310 using, for example, a chemical vapor deposition (CVD) method. The buffer layer 312 prevents a silicon layer from being contaminated by incorporated impurities from the transparent substrate 310. The buffer layer 312 may be omitted.

An amorphous silicon layer is deposited on the buffer layer 312 using, for example, the CVD method. Then, the amorphous silicon layer is crystallized into a polycrystalline layer 320 using a crystallization device that uses a laser beam. To control a threshold voltage of a polycrystalline TFT, impurities such as boron (B) may be ion-implanted into the polycrystalline silicon layer 320.

The polycrystalline silicon layer 320 is cleaned while a protrusion of the polycrystalline silicon layer 320 is removed or the height of the protrusion is reduced using the hydroxide etchant.

Referring to FIG. 5, the polycrystalline silicon layer 320 is patterned, in a photolithography process and an etching process, to form a polycrystalline silicon pattern 322 constituting an active region of the TFT.

Referring to FIG. 6, a gate insulating film 330 and a gate conductive film 340 are formed on the transparent substrate 310 having the polycrystalline silicon pattern 322 formed thereon. The gate insulating film 330 may comprise silicon oxide, silicon nitride or silicon oxynitride and can be formed using, for example, the CVD method. The gate conductive film 340 is formed using, for example, a physical vapor deposition (PVD) method. For example, the gate conductive film 340 may comprise aluminum (Al), aluminum-neodymium (AlNd), aluminum-molybdenum (AlMo), molybdenum (Mo), tungsten (W), titanium (Ti), titanium nitride (TiN), tantalum (Ta), or an alloy thereof. The gate conductive film 340 may have a single-layer or a multi-layer structure.

A photoresist pattern 350, defining a gate pattern, is formed on the gate conductive film 340.

Referring to FIG. 7, the gate conductive film 340 is etched using the photoresist pattern 350 as an etch mask to form a gate electrode 342. In an exemplary embodiment, the gate conductive film 340 may be dry-etched to form the gate electrode 342.

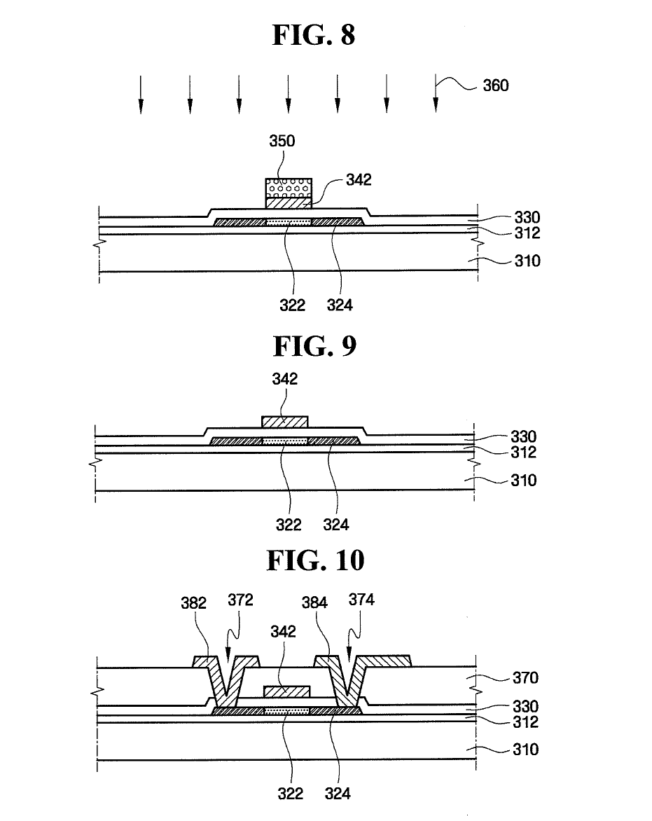

Referring to FIG. 8, high-concentration impurities 360 are ion-implanted into the resultant structure of FIG. 7 using the photoresist pattern 350 and the gate electrode 342 as ion-implantation masks. A heavily doped impurity region 324 is formed in the polycrystalline silicon pattern 322. In an exemplary embodiment, the impurities may be N-type impurities, such as PH₃, and may be ion-implanted with a dose of approximately 1.0×10¹⁵ atoms/cm² to approximately 5.0×10¹⁵ atoms/cm². The heavily doped impurity region 324 is aligned with the photoresist pattern 350 and the gate electrode 342.

Referring to FIGS. 8 and 9, the photoresist pattern 350 is removed. A lightly doped impurity region (not shown) may be formed adjacent the heavily doped impurity region 324 within the polycrystalline silicon pattern 322 using a separate ion implantation mask or an additional wet-etching process. Impurities used in an exemplary embodiment may be N-type impurities, such as PH₃, and may be ion-implanted with a dose of approximately 1.0×10¹² atoms/cm² to approximately 8.0×10¹² atoms/cm². The lightly doped impurity region may be referred to as a lightly doped drain (LDD) region. By forming the lightly doped impurity region, the kink effect and the generation of leakage current of the TFT can be restrained.

After the ion implantation process, annealing may be performed using, for example, a laser beam, rapid thermal annealing (RTA) or a furnace to diffuse impurities and to prevent an increase in electrical resistance due to the damage to a grain structure during the ion implantation process.

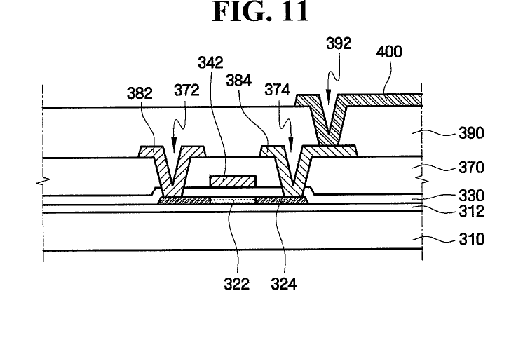

Referring to FIG. 10, an insulating material is formed on the gate electrode 342 and the gate insulating film 330 to form a first inter-layer insulating film 370. The first inter-layer insulating film 370 may comprise silicon oxide, silicon nitride or silicon oxynitride and can be formed using, for example, the CVD method. Then, the first inter-layer insulating film 370 is patterned to form a pair of contact holes 372 and 374 exposing the heavily doped impurity region 324 on both sides of the gate electrode 342.

After a data conductive film (not shown) is formed on the first inter-layer insulating film 370, the data conductive film is patterned to form a source electrode 382 and a drain electrode 384 within the contact holes 372 and 374, respectively. The source electrode 382 and the drain electrode 384 contact the heavily doped impurity region 324 through the contact holes 372 and 374, respectively. The data conductive film used for the source electrode 382 and the drain electrode 384 may be a single layer or multiple layers comprising aluminum (Al), aluminum-neodymium (AlNd), molybdenum (Mo), tungsten (W), neodymium (Nd), chrome (Cr), titanium (Ti), tantalum (Ta), or an alloy thereof. Alternatively, the data conductive film may comprise a material identical to that of the gate conductive film 340.

Referring to FIG. 11, an organic material, having photosensitivity and good planarization characteristics, is formed on the source electrode 382, the drain electrode 384 and the first inter-layer insulating film 370 to form a second inter-layer insulating film 390. The second inter-layer insulating film 390 may be formed by spin-coating an organic material such, for example, as acrylic resin.

Then, a contact hole 392 exposing the drain electrode 384 is formed in the second inter-layer insulating film 390.

A transparent material, such as indium tin oxide (ITO) or indium zinc oxide (IZO), is deposited in the contact hole 392 and on the second inter-layer insulating film 390 and then patterned to form a pixel electrode 400.

The breakdown voltages of the TFT manufactured by the method according to an exemplary embodiment were measured. Sample 1 refers to a TFT in which the protrusion of the polycrystalline silicon pattern was selectively etched and a silicon oxide film having a thickness of 75 nm was used as the gate insulating film. Sample 2 refers to a TFT in which the protrusion of the polycrystalline silicon pattern was not etched and a silicon oxide film having a thickness of 100 nm was used as the gate insulating film.

The breakdown voltage of Sample 1 was 44 V, and the breakdown voltage of Sample 2 was 46 V. Therefore, though a relatively thin gate insulating film is used, the gate insulating film can have a high breakdown voltage, and the electrical characteristic of the TFT can be improved.

In an exemplary embodiment, after the polycrystalline silicon layer 320 is patterned, the protrusion may be removed when the photoresist pattern 350 used for patterning the polycrystalline silicon layer 320 is stripped.

In a method of manufacturing a TFT according to an exemplary embodiment of the present invention, the height of a protrusion formed at a grain boundary is reduced to obtain uniform surface morphology, to prevent generation of leakage current and to increase the breakdown voltage of a gate insulating film. Consequently, a polycrystalline silicon TFT having good electrical characteristics can be implemented.

Although exemplary embodiments of the present invention have been described herein with reference to the accompanying drawings, it is to be understood that the present invention should not be limited thereto and that various other changes and modifications may be affected therein by one of ordinary skill in the related art without departing from the scope or spirit of the invention. All such changes and modifications are intended to be included within the scope of the invention.

What is claimed is:

1. A method of manufacturing a thin-film transistor (TFT), the method comprising:
forming an amorphous silicon layer on a substrate;
crystallizing the amorphous silicon layer into a polycrystalline silicon layer using a laser beam; and
selectively etching a protrusion formed at a grain boundary in the polycrystalline silicon layer using a hydroxide etchant.

2. The method of claim 1, wherein the hydroxide etchant has a higher etch rate for silicon than for silicon oxide.

3. The method of claim 2, wherein a silicon oxide film is formed on the polycrystalline silicon layer while the amorphous silicon layer is crystallized, and the silicon oxide film formed on the protrusion of the polycrystalline silicon layer is thinner than the silicon oxide film formed on portions of the polycrystalline silicon layer other than the protrusion.

4. The method of claim 1, wherein the hydroxide etchant comprises tetramethyl ammonium hydroxide (TMAH).

5. The method of claim 4, wherein the hydroxide etchant comprises about 1 wt % to about 5 wt % of TMAH, about 0.1 wt % to about 3 wt % of additives, and de-ionized water.

6. The method of claim 5, wherein the selective etching of the protrusion is performed at a temperature of about 60° C. to 90° C.

7. The method of claim 1, wherein the hydroxide etchant comprises potassium hydroxide (KOH).

8. The method of claim 7, wherein the hydroxide etchant comprises about 5 w % to about 15 wt % of KOH, about 0.1 wt % to about 3 wt % of additives, and de-ionized water.

9. The method of claim 8, wherein the selective etching of the protrusion is performed at a temperature of about 30° C. to 70° C.

10. The method of claim 1, wherein the selective etching of the protrusion is performed at an etch rate of about 5 nm/min to about 15 nm/min.

11. The method of claim 10, wherein polycrystalline silicon, forming the protrusion, has a (111) crystallographic orientation.

12. The method of claim 1, wherein the protrusion comprises an upper portion and a lower portion, wherein the upper portion has a narrower width and a steeper inclination than the lower portion, and the selective etching of the protrusion comprises removing the upper portion of the protrusion.

13. The method of claim 1, wherein a sequential lateral solidification (SLS) method is used in the crystallizing of the amorphous silicon layer.

14. The method of claim 1, further comprising:
forming a gate insulating film on the polycrystalline silicon layer;
forming a gate electrode on the gate insulating film; and
forming a source electrode and a drain electrode which are electrically connected to the polycrystalline silicon layer adjacent to both sides of the gate electrode.
